(19) United States
(12) Patent Application Publication
(10) Pub. No.: US 2008/0272432 A1
(43) Pub. Date: Nov. 6, 2008

(54) ACCUMULATION MODE MOS DEVICES AND METHODS FOR FABRICATING THE SAME

(75) Inventors: Niraj SUBBA, Sunnyvale, CA (US); Ciby THURUTHIYIL, Fremont, CA (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/687,813

(22) Filed: Mar. 19, 2007

(51) Int. Cl. H01L 29/786

(52) U.S. Cl. 257/347

(57) ABSTRACT

Accumulation mode MOS transistors and methods for fabricating such transistors are provided. A method comprises providing an SOI layer disposed overlying a substrate with an insulating layer interposed therebetween. The SOI layer is impurity doped with a first dopant of a first conductivity type and spacers and a gate stack having a sacrificial polycrystalline silicon gate electrode is formed on the SOI layer. A first and a second silicon region are impurity doped with a second dopant of the first conductivity type. The first silicon region and the second silicon region are aligned to the gate stack and spacers. The sacrificial polycrystalline silicon gate electrode is removed and a metal-comprising gate electrode is formed from a metal-comprising material having a mid-gap work function.

### FIELD OF THE INVENTION

The present invention generally relates to semiconductor devices and methods for fabricating the same, and more particularly relates to accumulation mode MOS transistors and methods for fabricating accumulation mode MOS transistors.

### BACKGROUND OF THE INVENTION

The majority of present day integrated circuits (ICs) are implemented by using a plurality of interconnected field effect transistors (FETs), also called metal oxide semiconductor field effect transistors (MOSFETs or MOS transistors). The ICs are usually formed using both P-channel FETs (“PMOS” transistors) and N-channel FETs (“NMOS” transistors) and the IC is then referred to as a complementary MOS or CMOS circuit. An MOS transistor is formed of a gate electrode that overlies a gate insulator disposed on a semiconductor layer. Source and drain regions are disposed within the semiconductor layer to the sides of the gate electrode. A channel is the portion of the semiconductor layer between the source and drain regions that underlies the gate electrode. The PMOS and NMOS transistors typically function as enhancement mode transistors, that is, when the transistor is turned on, the surface of the channel below the gate electrode becomes inverted. Thus, in a PMOS transistor, when the transistor is turned on, the interface becomes p-type. In an NMOS transistor, the interface becomes n-type when the transistor is turned on.

Polycrystalline silicon, or “polysilicon”, is conventionally employed as a gate electrode material in MOS transistors because it is relatively easy to deposit and accurately etch. In addition, polysilicon exhibits good thermal stability at high temperature processing. More specifically, the good thermal stability of polysilicon-based materials permits high temperature annealing thereof during formation/activation of implanted source and drain regions. Moreover, polysilicon-based materials advantageously block implantation of dopant ions into the underlying channel region of the transistor, thereby facilitating formation of self-aligned source and drain regions after gate electrode deposition and patterning is completed.

However, polysilicon-based gate electrodes can exhibit a number of drawbacks. For example, as device design rules decrease, polysilicon gates are adversely affected by poly depletion, wherein the effective gate oxide thickness (“EOT”) is increased. Such increase in EOT can reduce performance by about 15% or more. In addition, polysilicon-based gate electrodes have higher resistivities than most metal or metallic materials and thus devices including polysilicon as electrode or circuit materials operate at a much slower speed than equivalent devices utilizing metal-based materials. As a consequence, to compensate for the higher resistance, polysilicon-based materials require silicide processing to decrease their resistance and thus increase the operational speeds to acceptable levels.

In view of the above-described drawbacks associated with the use of polysilicon-based materials as gate electrodes in MOS and CMOS transistor devices, process schemes for making MOS and/or CMOS transistor devices with metal or metal-based gate electrodes have been proposed. Metal or metal-based gate electrode materials offer a number of advantages compared to conventional polysilicon-based materials, including: (1) because many metal materials are mid-gap work function materials, the same metal gate material can function as a gate electrode for both NMOS and PMOS transistors; (2) metal gate electrodes have a greater conductivity than polysilicon electrodes and do not require complicated silicide processing to perform at high operational speeds; and (3) unlike polysilicon-based gate electrodes, metal gate electrodes do not suffer from polysilicon depletion that affects the EOT of an MOS transistor, thereby affecting the performance of the MOS device (i.e., thinner EOTs, while possibly resulting in an increased leakage current, result in faster operating devices).

The use of metal or metallic materials as replacements for polysilicon-based materials as gate electrodes in MOS and/or CMOS devices incurs several difficulties, however, that must be considered and overcome in any metal-based gate electrode process scheme, including: (1) metal and/or metal-based gates cannot withstand the higher temperatures and oxidative ambients that conventional polysilicon-based gate electrode materials can withstand; and (2) thermal processing subsequent to metal gate electrode formation may result in instability and degradation of the gate oxide due to chemical interaction between the metal and oxide at the metal gate-gate oxide interface.

Accordingly, it is desirable to provide MOS transistors with metal gates and gate oxides that are not damaged by high temperature processing. In addition, it is desirable to provide methods for fabricating MOS transistors with metal gates and gate oxides that are not damaged by high temperature processing. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

Accumulation mode MOS devices and methods for fabricating accumulation mode MOS devices are provided. In accordance with an exemplary embodiment of the invention, the method comprises providing an SOI layer disposed overlying a substrate. An insulating layer is interposed between the SOI layer and the substrate. The SOI layer is impurity doped with a first dopant of a first conductivity type and spacers and a gate stack having a sacrificial polycrystalline silicon gate electrode are formed on the SOI layer. A first silicon region and a second silicon region are impurity doped with a second dopant of the first conductivity type. The first silicon region and the second silicon region are aligned to the gate stack and spacers. The sacrificial polycrystalline silicon gate electrode is removed and a metal-comprising gate electrode is formed from a metal-comprising material having a mid-gap work function.

### BRIEF DESCRIPTION OF THE DRAWINGS

The present invention will hereinafter be described in conjunction with the following drawing figures, wherein like numerals denote like elements, and wherein:

FIG. 1 is a cross-sectional view of an accumulation mode MOS transistor in accordance with an exemplary embodiment of the present invention;

FIG. 2 is a cross-sectional view of an accumulation mode MOS transistor in accordance with another exemplary embodiment of the present invention; and

FIGS. 3-18 illustrate, in cross section, a method for fabricating an MOS transistor in accordance with an exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

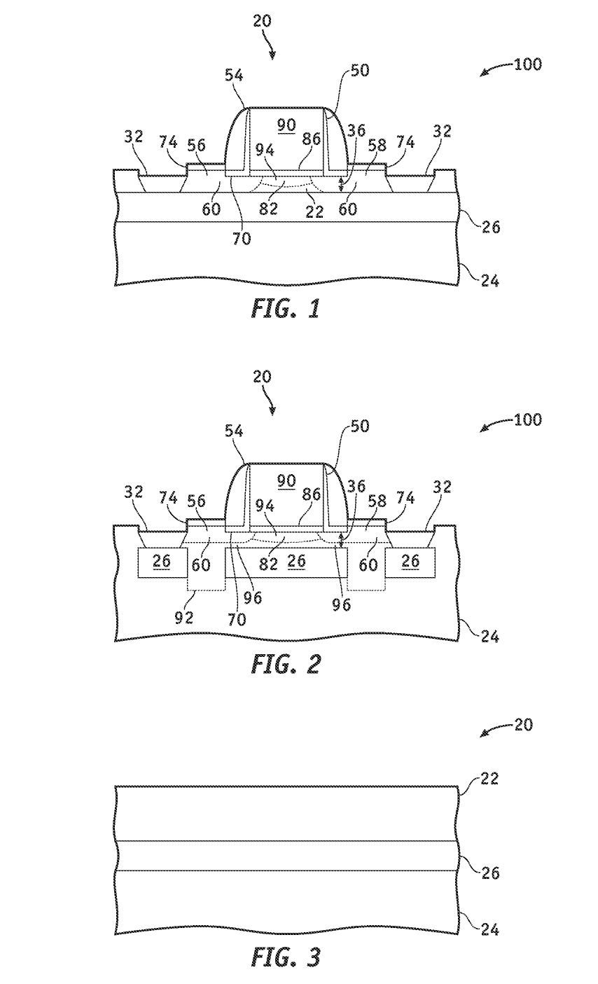

FIG. 1 is a cross-sectional view of a semiconductor device 100 having an accumulation mode MOS transistor 20 in accordance with an exemplary embodiment of the present invention. An accumulation mode MOS transistor is a transistor having source and drain regions that are doped with impurities so that they have the same conductive type as that of the channel region and, hence, the same conductive type as that of the carriers introduced into the channel. The accumulation mode MOS transistor provides for a thin CMOS device that has single work function metal-based gate electrodes that are not damaged by high temperature processing during fabrication of the CMOS device. Accumulation mode MOS transistor 20 can be a PMOS transistor or an NMOS transistor. Various steps in the manufacture of MOS components are well known and so, in the interest of brevity, many conventional steps will only be mentioned briefly herein or will be omitted entirely without providing the well known process details. While semiconductor device 100 is illustrated with only one accumulation mode MOS transistor, it will be appreciated that semiconductor device 100 may have any number of accumulation mode NMOS transistors and/or PMOS transistors. Those of skill in the art will appreciate that device 100 may include a large number of such transistors as required to implement a desired circuit function.

Accumulation mode MOS transistor 20 is formed on and within a silicon-on-insulator (SOI) layer 22 that is disposed on a silicon substrate 24. As used herein, the terms “SOI layer” and “silicon substrate” will be used to encompass the relatively pure or lightly impurity-doped monocrystalline silicon materials typically used in the semiconductor industry as well as silicon admixed with other elements such as germanium, carbon, and the like to form substantially monocrystalline semiconductor material. SOI layer 22 is doped with an impurity dopant of a conductivity type. For example, if MOS transistor 20 is an NMOS transistor, SOI layer can be doped with arsenic or phosphorous ions. If MOS transistor 20 is a PMOS transistor, SOI layer 22 can be doped with boron ions. Source and drain regions 60 are disposed within SOI layer 22. The region of SOI layer 22 between the source and drain regions 60 is the channel region 94. As noted above, source and drain regions 60 are doped with an impurity dopant of the same conductivity type as the impurity dopant implanted in SOI layer 22, that is, in the channel region 94. SOI layer 22 has a thickness, illustrated by double-headed arrow 36, within the channel region 94 such that the channel region is substantially fully depleted when the gate-source voltage (V_{gs}) is zero. Thus, when V_{gs} is about zero, substantially no current flows from the source to the drain. In a preferred embodiment of the present invention, the SOI layer 22 has a thickness 36 of about 2 to about 15 nm. In a more preferred embodiment, the thickness 36 is about 5 to about 10 nm.

An insulating layer 26 is disposed between the SOI layer 22 and the silicon substrate 24. The insulating layer 26 typically comprises, for example, silicon oxide and has a thickness in the range of about 100 to about 200 nm. The MOS transistor 20 is electrically isolated from other transistors (not shown) by dielectric isolation regions 32, preferably shallow trench isolation (STI) regions.

Accumulation mode MOS transistor 20 further comprises raised regions 56 and 58. Source and drain regions 60 extend from raised regions 56 and 58 to a portion of SOI layer 22. In accordance with one exemplary embodiment of the present invention, the raised regions 56 and 58 are epitaxially grown silicon layers that, as described in more detail below, are grown on SOI layer 22 using selective epitaxial growth. The raised regions 56 and 58 have a height as measured from a surface 70 of the SOI layer 22 that is about at least the height of gate insulator 86. Referring momentarily to FIG. 2, in accordance with another exemplary embodiment of the present invention, the raised regions 56 and 58 extend from a surface 92 of silicon substrate 24 and have a height, as measured from surface 70 of the SOI layer 22 equal to about at least the height of gate insulator 86. In one embodiment, the raised regions 56 and 58 may be doped with a dopant of a conductivity type opposite to that of the source and drain regions 60 to separate the source and drain regions 60 from a semiconductor substrate 24 of the same conductivity type, such as when a PMOS transistor 20 is formed on a p-type semiconductor substrate or when an NMOS transistor 20 is formed on an n-type semiconductor substrate.

Referring to FIGS. 1 and 2, MOS transistor 20 further includes a gate insulator 86 formed at the SOI layer 22 surface. The gate insulator 86 may be a thermally grown silicon dioxide formed by heating the SOI layer in an oxidizing ambient, or may be a deposited insulator such as silicon oxide, silicon nitride, a high dielectric constant insulator such as HfSiO, or the like. The gate insulator 86 is typically 1-10 nanometers (nm) in thickness. A gate electrode 90 comprising metal or a metal-based material overlies the gate insulator 86. In an exemplary embodiment of the invention, the metal or metal-based material is any material that permits substantially full depletion of the channel region, that is, the region of SOI layer 22 below the gate electrode 90, when the gate-source voltage (V_{gs}) is zero, whether the MOS transistor 20 is an n-channel or a p-channel device. In a preferred embodiment of the invention, the metal or metal-based material is a metal-comprising material having a work function in the range of about 4.5 eV to about 4.9 eV. In a more preferred embodiment of the invention, the metal or metal-based material is a metal-comprising material having a work function of about 4.7 eV such as, for example, copper. Accordingly, for an accumulation mode n-channel transistor having a metal gate with a mid-gap work function, the channel region is substantially depleted of majority carriers when V_{gs} is zero. As V_{gs} becomes more positive, the channel region begins to accumulate with majority carriers (i.e., electrons) and will begin to conduct current. For a p-channel accumulation mode transistor having a metal gate with a mid-gap work function, the channel region also is substantially depleted of majority carriers when V_{gs} is zero. As V_{gs} becomes more negative, the channel region begins to accumulate with majority carries (i.e., holes) and will begin to conduct current. In this regard, unlike enhancement mode MOSFETs, majority carriers are the key contributor to the flow of current from source to drain in accumulation mode MOS transistors. A sidewall oxide layer 50 is disposed on the sidewalls of the gate electrode and a sidewall spacer 54 is disposed adjacent the sidewall oxide layer 50. The sidewall spacer 54 comprises, for example, silicon oxide, silicon nitride, or the like.

FIGS. 3-18 illustrate a method for forming an accumulation mode MOS transistor, such as accumulation mode MOS transistor 20, in accordance with various exemplary embodiments of the present invention. MOS transistor 20 can be a PMOS or an NMOS transistor. While FIGS. 3-18 illustrate the formation of one MOS transistor 20, it will be appreciated that the various embodiments of the present invention can be used to fabricate any number of PMOS and NMOS transistors of a semiconductor device. Referring to FIG. 3, the method for fabricating MOS transistor 20 in accordance with one embodiment of the invention begins with SOI layer 22 overlying silicon substrate 24. An insulating layer 26 is disposed between the SOI layer and the silicon substrate 24.

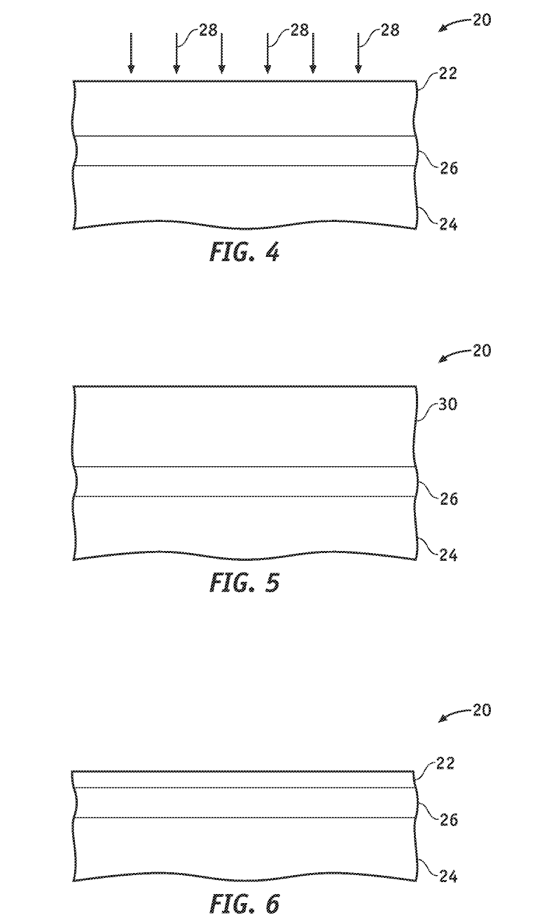

FIG. 4 illustrates one method and FIGS. 5 and 6 illustrate an alternate method, both in accordance with embodiments of the invention, for forming SOI layer 22 overlying silicon substrate 24. FIG. 4 illustrates a process for forming a thin SOI layer 22 by the SIMOX process. The SIMOX process is a well known process in which oxygen ions are implanted into a sub-surface region of silicon substrate 24, as indicated by arrows 28. The silicon substrate and the implanted oxygen are subsequently heated to form a sub-surface silicon oxide layer 26 that electrically isolates SOI layer 22 from the remaining portion of silicon substrate 24. The thickness of SOI layer 22 is determined by the energy of the implanted ions; that is, the implant energy is adjusted so that the range of the implanted oxygen ions just exceeds the intended thickness of SOI layer 22.

In the alternate embodiment illustrated in FIGS. 5 and 6, SOI layer 22 is formed by a process of wafer bonding. As illustrated in FIG. 5, a layer of insulating material 26, such as silicon dioxide, is formed on the upper surface of silicon substrate 24 and/or on the surface of a second silicon wafer 30. Wafer 30 is bonded to silicon substrate 24 so that insulating material 26 separates silicon substrate 24 and second silicon wafer 30. As illustrated in FIG. 6, the second silicon wafer is thinned, for example by chemical mechanical planarization (CMP), to leave a thin SOI layer 22 on insulating layer 26 overlying silicon substrate 24.

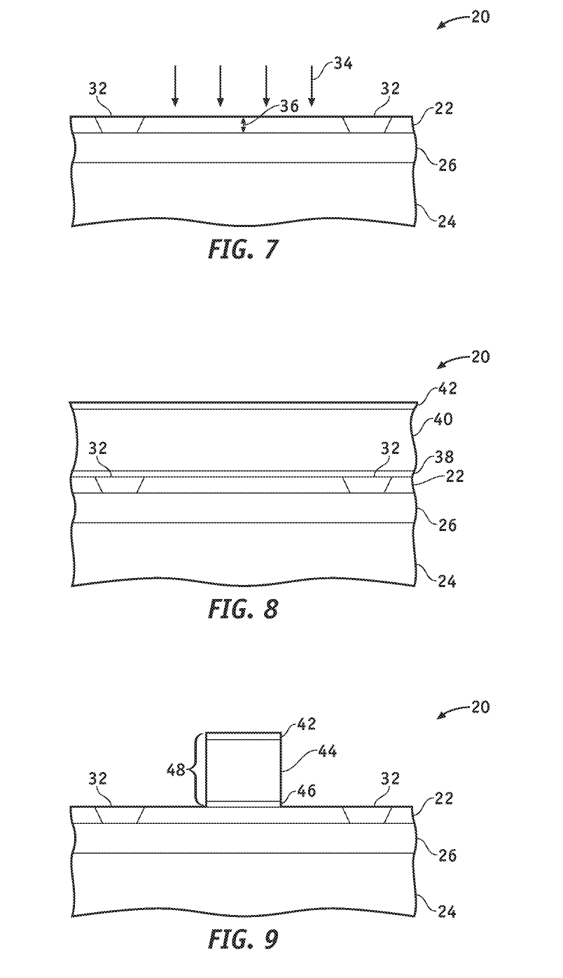

As illustrated in FIG. 7, in accordance with an exemplary embodiment of the present invention, whether formed by a SIMOX process or by a wafer bonding process, the SOI layer 22 is fabricated to have a thickness, illustrated by double-headed arrow 36, so that, upon formation of an accumulation mode MOS transistor thereon, the region of the SOI layer 22 underneath the gate of the transistor is substantially fully depleted when the gate voltage (V_{gs}) is zero. In a preferred embodiment of the present invention, the SOI layer 22 has a thickness 36 of about 2 to about 15 nm. In a more preferred embodiment, the thickness 36 is about 5 to about 10 nm. Dielectric isolation regions 32, preferably shallow trench isolation (STI) regions, are formed within SOI layer 22, preferably extending to insulating layer 26, to electrically isolate subsequently-formed MOS transistor 20 from other MOS transistors. As is well known, there are many processes that can be used to form the STI, so the process need not be described here in detail. In general, STI includes a shallow trench that is etched into the surface of SOI layer 22 to the insulating layer 26 and that is subsequently filled with an insulating material. After the trench is filled with an insulating material such as silicon oxide, the surface is usually planarized, for example by CMP. Following the formation of the shallow trench isolation, SOI layer 22 is appropriately impurity doped in known manner, for example, by ion implantation and subsequent thermal annealing of dopant ions, illustrated by arrows 34. For an n-channel MOS transistor, the SOI layer 22 is preferably formed by implanting arsenic ions, although phosphorus ions could also be used. For a p-channel MOS transistor, the SOI layer 22 is preferably formed by implanting boron ions.

Referring to FIG. 8, the method continues, in accordance with an exemplary embodiment of the present invention, with the formation of a gate stack overlying SOI layer 22. A layer of gate insulator 38 is formed on the surface of SOI layer 22. The gate insulator may be a thermally grown silicon dioxide formed by heating the SOI layer in an oxidizing ambient, or may be a deposited insulator such as a silicon oxide, silicon nitride, a high dielectric constant insulator such as HfSiO, or the like. Deposited insulators can be deposited by chemical vapor deposition (CVD), low pressure chemical vapor deposition (LPCVD), or plasma enhanced chemical vapor deposition (PECVD). The gate insulator material is typically 1-10 nanometers (nm) in thickness. In accordance with one embodiment of the invention, a layer of sacrificial polycrystalline silicon 40 is deposited overlying the layer of gate insulator. The polycrystalline silicon can be deposited, for example, by LPCVD by the hydrogen reduction of silane. The polycrystalline silicon is deposited to a thickness in the range of about 80 to about 150 nm. An antireflective coating (ARC) 42 is deposited overlying polycrystalline silicon. A layer (not shown) of hard mask material such as silicon nitride, or silicon oxynitride is deposited onto the surface of the ARC layer 42. The hard mask material can be deposited to a thickness of about 30 nm, also by LPCVD. The hard mask layer is photolithographically patterned and the underlying ARC layer 42, polycrystalline silicon layer 40, and gate insulator layer 38 are etched to form a gate stack 48 having a sacrificial polycrystalline silicon gate electrode 44 and gate insulator 46, as illustrated in FIG. 9. The polycrystalline silicon can be etched in the desired pattern by, for example, reactive ion etching (RIE) using a Cl⁻ or HBr/O₂ chemistry and the hard mask and gate insulator can be etched, for example, by RIE in a CHF₃, CF₄, or SF₆ chemistry.

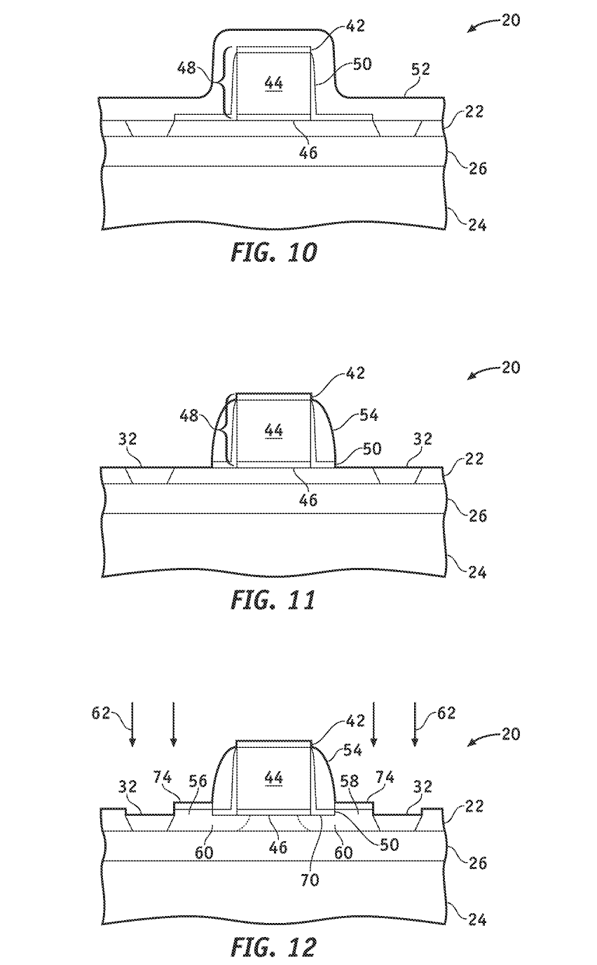

Referring to FIG. 10, a sidewall gate oxidation is performed to form sidewall oxidation layer 50. A blanket layer 52 of spacer-forming material such as silicon oxide or silicon nitride is deposited over the gate stack 48 and SOI layer 22. The layer of spacer-forming material can be deposited, for example, to a thickness of about 50-500 nm by LPCVD. Layer 52 of spacer-forming material is anisotropically etched, for example by RIE using a CHF₃, CF₄, or SF₆ chemistry, to form sidewall spacers 54 on each sidewall of gate electrode 44, as illustrated in FIG. 11. Although some integrated circuits fabrication processes may use additional spacers, such additional process steps are not necessary to illustrate the invention and hence need not by shown.

Referring to FIG. 12, in accordance with one exemplary embodiment of the present invention, a selective epitaxy is then performed to grow a second semiconductor layer overlying SOI layer 22 to form a first raised region 56 and a second raised region 58. The epitaxial silicon layer can be grown by the reduction of silane (SiH₄) or dichlorosilane (SiH₂Cl₂) in the presence of HCl. The presence of the chlorine source promotes the selective nature of the growth, that is, the growth of the epitaxial silicon preferentially on the exposed silicon surfaces as opposed to on the isolation regions 32. Growth of the second semiconductor layer improves the resistance of subsequently-formed source drain regions and permits improved contact to the source and drain regions. The second semiconductor layer may be silicon, silicon germanium, or silicon carbide. In an exemplary embodiment of the invention, the second semiconductor layer has a height, as measured from a surface 70 of SOI layer 22, that is about equal to at least the height of gate insulator 46.

Gate stack 48, sidewall oxidation layer 50, and sidewall spacers 54 then can be used as an ion implantation mask to form source and drain regions 60 in SOI layer 22. In this regard, SOI layer 22 is appropriately impurity doped in known manner, for example, by ion implantation and subsequent thermal annealing of dopant ions, illustrated by arrows 62. Dopant ions 62 are of the same conductivity as the dopant ions 34 of FIG. 5. Accordingly, for an n-channel MOS transistor, the source and drain regions 60 are preferably formed by implanting arsenic ions, although phosphorus ions could also be used. For a p-channel MOS transistor, the source and drain regions 60 are preferably formed by implanting boron ions. MOS transistor 20 then can be subjected to an anneal, such as rapid thermal anneal (RTA), to activate the impurities in the source and drain regions 60. Regions 60 thus will be self aligned with spacers 54 and the gate stack 48.

A layer of silicide-forming metal is deposited onto the surface of the source and drain regions 60 and on the ARC layer 42 overlying gate stack 48 and is heated, for example by RTA, to form a metal silicide layer 74 at the top of each of the first and second raised regions 56 and 58, as also illustrated in FIG. 12. The ARC layer 42 prevents formation of metal silicide on the polycrystalline silicon gate electrode 44. The silicide-forming metal can be, for example, cobalt, nickel, rhenium, ruthenium, or palladium, and preferably is either cobalt, nickel, or nickel alloy with other metals. The silicide-forming metal can be deposited, for example, by sputtering to a thickness of about 5-15 nm and preferably to a thickness of about 10 nm. Any silicide-forming metal that is not in contact with exposed silicon, for example the silicide-forming metal that is deposited on the sidewall spacers 54 and on ARC layer 42, does not react during the RTA to form a silicide and may subsequently be removed by wet etching in a H₂O₂/H₂SO₄ or HNO₃/HCl solution. The sidewall spacers restrict the formation of silicide layer 74 so that the metal silicide formed on the source and drain regions will not contact a subsequently-formed metal gate electrode, which would cause an electrical short between the gate electrode and the source and/or drain region.

Referring momentarily to FIGS. 17 and 18, in accordance with an alternative exemplary embodiment of the present invention, instead of epitaxially growing a second semiconductor layer on the SOI layer 22, the gate stack 48, sidewall oxidation layer 50, and sidewall spacers 54 can be used as an etch mask to etch SOI layer 22, insulating layer 26, and a portion of silicon substrate 24. In this regard, as illustrated in FIG. 17, a layer of photoresist (not shown) may be applied and photolithographically patterned to protect gate stack 48, sidewall spacers 54, sidewall oxide layer 50, and isolation regions 32. Trenches 66 then are etched through SOI layer 22, insulating layer 26, and into the upper portion of silicon substrate 24. The trench can be etched by RIE using a CF₄ or CHF₃ chemistry to etch the insulator layer and a chlorine or hydrogen bromide chemistry to etch the silicon. The photoresist layer is removed after completing the etching of trenches 66.

Referring to FIG. 18, a selective epitaxy is then performed to grow a second semiconductor layer overlying silicon substrate 24 to form a first raised region 56 and a second raised region 58. In an exemplary embodiment of the invention, the second semiconductor layer has a height measured from surface 70 of the SOI layer 22 equal to about at least the height (e.g. thickness) of gate insulator 46. Gate stack 48, sidewall oxidation layer 50, and sidewall spacers 54 then can be used as an ion implantation mask to form source and drain regions 60 in first and second raised regions 56 and 58 and SOI layer 22. In this regard, SOI layer 22 and first and second raised regions 56 and 58 are appropriately impurity doped in known manner, for example, by ion implantation and subsequent thermal annealing of dopant ions, illustrated by arrows 72. Dopant ions 72 are of the same conductivity as the dopant ions 34 of FIG. 5. MOS transistor 20 then can be subjected to an anneal, such as rapid thermal anneal (RTA), to activate the impurities in the source and drain regions 60. Regions 60 thus will be self aligned with spacers 54 and the gate stack 48. As further illustrated in FIG. 18, if the source and drain regions 60 will be of the same conductivity type as the semiconductor substrate 24, an in-situ doping of ions of an opposite conductivity type can be performed after or, preferably, during the epitaxial growth process to form raised regions 56 and 58 of the opposite conductivity type. For example, if p-type source and drain regions 60 are to be formed on a p-type semiconductor substrate, the raised regions 56 and 58 can be formed as n-type regions. Similarly, if n-type source and drain regions 60 are to be formed on an n-type semiconductor substrate, the raised regions 56 and 58 can be formed as p-type regions. After formation of the source and drain regions 60, metal silicide layers 74 then can be formed on raised regions 56 and 58, as described above.

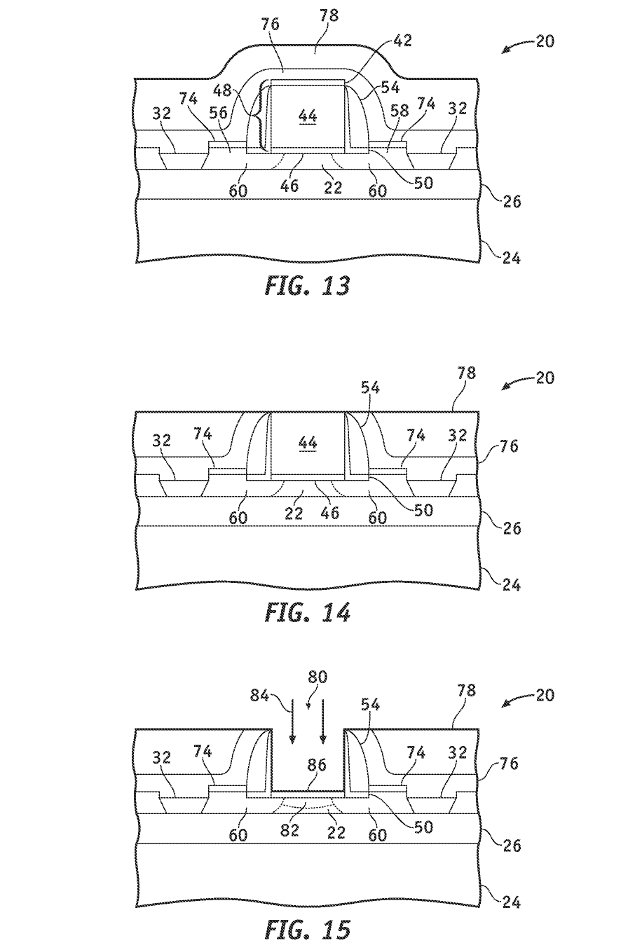

Referring to FIG. 13, after the formation of metal silicide layers 74, whether formed in accordance with the method steps illustrated in FIG. 12 or in FIGS. 17 and 18, the method continues in accordance with an exemplary embodiment of the invention with the formation of a nitride layer 76 overlying gate stack 48, sidewall oxidation layer 50, sidewall spacers 54, and metal silicide layers 74. The nitride layer 76 may be formed by, for example, PECVD. A blanket-deposited dielectric layer 78 is deposited on nitride layer 76. The dielectric layer may be formed from, for example, tetraethylorthosilicate (TEOS). As illustrated in FIG. 14, the dielectric layer 78 and the nitride layer 76, along with ARC layer 42, then are planarized to expose the polycrystalline silicon gate electrode 44. Preferably, the planarization is performed using CMP.

The sacrificial polycrystalline silicon gate electrode 44 then is removed, exposing gate insulator 46 and forming a feature opening 80, as illustrated in FIG. 15. Gate electrode 44 may be removed by, for example, RIE in a chlorine plasma or by wet polycrystalline silicon etching. The threshold voltage (Vₜ) optionally is adjusted, as needed, by means of ion implantation, represented by arrows 84, through the feature opening 80 and the gate insulator 46 to form Vₜ doped region 82 within SOI layer 22. Gate insulator layer 46 typically is a sacrificial oxide layer that is removed and replaced with a high-k gate dielectric layer 86.

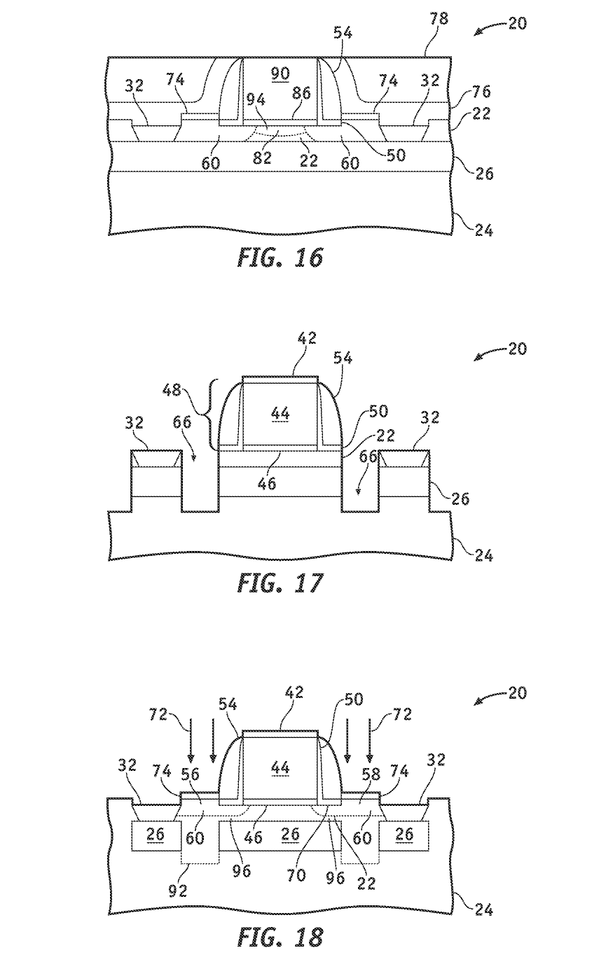

As illustrated in FIG. 16, a layer of metal or metal-based material is deposited within feature opening 80. Any overburden or excess metal or metal-based material can be removed from the surface of dielectric layer 78 by, for example, CMP to form a metal-comprising gate electrode 90. In an exemplary embodiment of the invention, the metal or metal-based material can comprise any material that permits substantially full depletion of the channel region 94, that is, the region of SOI layer 22 below the gate electrode 90, when the gate-source voltage (V_{gs}) is zero, whether the accumulation mode MOS transistor 20 is an n-channel or a p-channel device. In a preferred embodiment of the invention, the metal or metal-based material is a metal-comprising material having a work function in the range of about 4.5 eV to about 4.9 eV. In a more preferred embodiment of the invention, the metal or metal-based material is a metal-comprising material having a work function of about 4.7 eV such as, for example, copper.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating an MOS transistor, the method comprising the steps of:
providing an SOI layer disposed overlying a substrate, wherein an insulating layer is interposed between the SOI layer and the substrate;
impurity doping the SOI layer with a first dopant of a first conductivity type;
forming a gate stack and spacers on the SOI layer, wherein the gate stack has a sacrificial polycrystalline silicon gate electrode;
impurity doping a first silicon region and a second silicon region with a second dopant of the first conductivity type, wherein the first silicon region and the second silicon region are aligned to the gate stack and spacers;
removing the sacrificial polycrystalline silicon gate electrode; and
forming overlying the SOI layer a metal-comprising gate electrode from a metal-comprising material having a mid-gap work function.

2. The method of claim 1, wherein the step of providing an SOI layer comprises the step of providing an SOI layer having a thickness under the gate stack such that a channel region of the SOI layer is substantially fully depleted when a gate-source voltage (V_{gs}) applied to the metal-comprising gate electrode is zero.

3. The method of claim 2, wherein the step of providing an SOI layer comprises the step of providing an SOI layer having a thickness in a range of about 5 to about 10 nm.

4. The method of claim 1, wherein the step of forming a metal-comprising gate electrode from a metal-comprising material having a mid-gap work function comprises the step of forming a metal-comprising gate electrode from a metal-comprising material having a work function in a range of about 4.5 eV to about 4.9 eV.

5. The method of claim 4, wherein the step of forming a metal-comprising gate electrode from a metal-comprising material having a mid-gap work function comprises the step of forming a metal-comprising gate electrode from a metal-comprising material having a work function of about 4.7 eV.

6. The method of claim 1, further comprising the step of epitaxially growing silicon on the SOI layer to form raised regions proximate to the gate stack, wherein the step of epitaxially growing is performed after the step of forming the gate stack and spacers on the SOI layer and before the step of impurity doping.

7. The method of claim 6, further comprising the step of forming metal silicide layers on the raised regions.

8. The method of claim 1, further comprising, after the step of forming a gate stack and spacers, the steps of:
etching trenches through the SOI layer and the insulating layer and into the substrate using the gate stack as an etch mask; and
epitaxially growing a semiconductor material on the substrate to form raised regions proximate to the gate stack, wherein the step of epitaxially growing is performed before the step of impurity doping a first silicon region and a second silicon region.

9. The method of claim 8, wherein the step of epitaxially growing a semiconductor material on the substrate to form raised regions further comprises the step of impurity doping the raised regions with a dopant of a second conductivity type, wherein the first conductivity type is not the second conductivity type.

10. The method of claim 8, further comprising the step of forming metal silicide layers on the raised regions.

11. The method of claim 1, further comprising the step of implanting ions into the SOI layer, the step of implanting performed after the step of removing the sacrificial polycrystalline silicon gate electrode and before the step of forming a metal-comprising gate electrode.

12. A method for fabricating an accumulation mode MOS transistor, the method comprising the steps of:
providing a semiconductor substrate with an SOI layer of a first conductivity type thereon;
forming a sacrificial polysilicon gate electrode overlying the SOI layer;
implanting dopants of the first conductivity type into the SOI layer using the sacrificial polysilicon gate electrode as an implantation mask;
removing the sacrificial polysilicon gate electrode; and
replacing the sacrificial polysilicon gate electrode with a metal-comprising gate electrode having a mid-gap work function.

13. The method of claim 12, wherein the step of providing a semiconductor substrate with an SOI layer of a first conductivity type thereon comprises the step of providing a semiconductor substrate with an SOI layer having a thickness such that a channel region of the SOI layer is substantially fully depleted when a gate-source voltage (V_{gs}) applied to the metal-comprising gate electrode is zero.

14. The method of claim 12, wherein the step of providing a semiconductor substrate with an SOI layer of a first conductivity type thereon comprises the step of providing a semiconductor substrate with an SOI layer having a thickness in the range of about 5 to about 10 nm thereon.

15. The method of claim 12, further comprising the step of epitaxially growing a semiconductor material to form raised regions about the sacrificial polysilicon gate electrode, wherein the step of epitaxially growing is performed after the step of forming a sacrificial polysilicon gate electrode overlying the silicon layer and before the step of implanting dopants of the first conductivity type into the SOI layer using the sacrificial polysilicon gate electrode as an implantation mask.

16. The method of claim 15, wherein the step of epitaxially growing comprises epitaxially growing the semiconductor material on the SOI layer.

17. The method of claim 15, wherein the step of epitaxially growing comprises the steps of:
etching trenches through the SOI layer and into the substrate; and
epitaxially growing the semiconductor material on the substrate.

18. The method of claim 17, further comprising the step of simultaneously impurity doping the epitaxially-grown semiconductor material as it is grown with a dopant of a second conductivity type, wherein the first conductivity type is not the second conductivity type.

19. The method of claim 12, wherein the step of replacing the sacrificial polysilicon gate electrode with a metal-comprising gate electrode having a mid-gap work function comprises the step of replacing the sacrificial polysilicon gate electrode with a metal-comprising gate electrode having a work function in a range of about 4.5 eV to about 4.9 eV.

20. An accumulation mode MOS transistor comprising:
an SOI layer disposed on a substrate, the SOI layer having a first portion with a first concentration of first dopants;
a gate stack disposed overlying the first portion of the SOI layer, wherein the gate stack includes a metal-comprising gate electrode formed of a metal-comprising material with a mid-gap work function;
a first region of semiconductor material disposed overlying the substrate and aligned to the gate stack and having a second concentration of second dopants; and
a second region of semiconductor material disposed overlying the substrate and aligned to the gate stack, and having the second concentration of the second dopants, wherein the first dopants and the second dopants are of the same conductivity type.
